(19) United States
(12) Patent Application Publication
(10) Pub. No.: US 2023/0356590 A1
(43) Pub. Date: Nov. 9, 2023

(54) CIRCUIT APPARATUS

(71) Applicants: AutoNetworks Technologies, Ltd., Yokkaichi-shi, Mie (JP); Sumitomo Wiring Systems, Ltd., Yokkaichi-shi, Mie (JP); Sumitomo Electric Industries, Ltd., Osaka-shi, Osaka (JP)

(72) Inventors: Shinnosuke NAKAGUCHI, Yokkaichi-shi, Mie (JP); Masayuki KATO, Yokkaichi-shi, Mie (JP)

(21) Appl. No.: 18/044,488

(22) PCT Filed: Jul. 21, 2021
(86) PCT No.: PCT/JP2021/027363

§ 371 Date: Mar. 8, 2023

(30) Foreign Application Priority Data
Sep. 14, 2020 (JP) 2020-153779

(51) Int. Cl. B60K 35/00; H05K 1/02

(52) U.S. Cl. CPC B60K 35/00; H05K 1/0296; B60K 2370/42; H05K 2201/10272; H05K 2201/10689

(57) ABSTRACT

A circuit apparatus is mounted in a vehicle. In a circuit board, a plurality of first conductive patterns and a second conductive pattern are disposed on an insulating layer. An integrated circuit device is disposed on the plurality of first conductive patterns. The integrated circuit device is electrically connected to the plurality of first conductive patterns. A busbar is connected to the second conductive pattern.

### CROSS-REFERENCE TO RELATED APPLICATIONS

This application is the U.S. national stage of PCT/JP2021/027363 filed on Jul. 21, 2021, which claims priority of Japanese Patent Application No. JP 2020-153779 filed on Sep. 14, 2020, the contents of which are incorporated herein.

### TECHNICAL FIELD

The present disclosure relates to a circuit apparatus.

### BACKGROUND

JP 2019-121617A discloses a vehicle circuit apparatus provided with an integrated circuit device. In this circuit apparatus, the integrated circuit device is disposed on one surface of a circuit board. The integrated circuit device is electrically connected to a plurality of conductive patterns included in the circuit board. The integrated circuit device outputs a signal to a circuit device via a conductive pattern, for example.

In a circuit board, usually, a plurality of first conductive patterns that are electrically connected to an integrated circuit device and second conductive patterns that differ from the first conductive patterns are disposed on an insulating layer. The first conductive patterns and the second conductive patterns are normally plate-shaped. When there are many first conductive patterns, the first conductive patterns are disposed in close proximity to each other. Thus, the width of the first conductive patterns is small, and the distance between two adjacent first conductive patterns is small. The thickness of the first conductive patterns and the second conductive patterns is determined by the smallest interval between the two conductive patterns of the first conductive patterns and second conductive patterns that are closest to each other and provided on the same insulating layer. The smaller the smallest interval, the smaller the thickness of the first conductive patterns and second conductive patterns.

Thus, the aforementioned smallest interval is small when there are many first conductive patterns electrically connected to the integrated circuit device, and thus the thickness of the second conductive patterns is small, and the cross-sectional area of the second conductive patterns is small. When the second conductive patterns have a small cross-sectional area, the resistance value of the second conductive patterns is large. Thus, there is the issue of a current being unable to flow through the second conductive patterns.

Thus, it is an object to provide a circuit apparatus in which a large current can flow through a second conductive pattern disposed on the same insulating layer as first conductive patterns that are electrically connected to an integrated circuit device.

### SUMMARY

A circuit apparatus according to an aspect of the present disclosure is a circuit apparatus to be mounted in a vehicle, including: an insulating layer; a plurality of first conductive patterns and a second conductive pattern disposed on the insulating layer; an integrated circuit device disposed on and electrically connected to the plurality of first conductive patterns; and a busbar that is connected to the second conductive pattern.

According to the present disclosure, a large current can flow through a second conductive pattern disposed on the same insulating layer as the first conductive patterns that are electrically connected to the integrated circuit device.

### BRIEF DESCRIPTION OF DRAWINGS

FIG. 1 is a plan view of a circuit apparatus of Embodiment 1.

FIG. 2 is a block view showing main configurations of the circuit apparatus.

FIG. 3 is a side view of the circuit apparatus.

FIG. 4 is a cross-sectional view of the circuit apparatus taken along line A-A in FIG. 1.

FIG. 5 is a side view of an integrated circuit device.

FIG. 6 is a bottom view of the integrated circuit device.

FIG. 7 is a diagram for describing the location of an electrode of the integrated circuit device.

FIG. 8 is a diagram for describing connection of first conductive patterns to the integrated circuit device.

FIG. 9 is a diagram for describing a relation between the smallest interval and the thickness of a conductive pattern.

FIG. 10 is a diagram for describing an effect of a busbar.

FIG. 11 is a side view of a circuit apparatus according to Embodiment 2.

FIG. 12 is a diagram for describing connection between a second conductive pattern and a connection portion.

### DETAILED DESCRIPTION OF PREFERRED EMBODIMENTS

First, embodiments of the present disclosure will be listed and described. At least some of the embodiments described below may be combined as appropriate.

A circuit apparatus according to an aspect of the present disclosure is a circuit apparatus to be mounted in a vehicle, including: an insulating layer; a plurality of first conductive patterns and a second conductive pattern disposed on the insulating layer; an integrated circuit device disposed on and electrically connected to the plurality of first conductive patterns; and a busbar that is connected to the second conductive pattern.

In this aspect, the first conductive patterns and the second conductive pattern are plate-shaped. The plurality of first conductive patterns are electrically connected to the integrated circuit device, and thus the first conductive patterns are in close proximity to each other. When there are many first conductive patterns, the width of the first conductive patterns is small, and the thickness of the first conductive patterns is small. The first conductive patterns and second conductive pattern are disposed on the same insulating layer, and thus the thickness of the second conductive pattern is the same as the thickness of the first conductive patterns and therefore thin. However, a busbar is connected to the second conductive pattern. Thus, the second conductive pattern and the busbar function as a first conductive wire that has a large cross-sectional area in a state where they overlap each other. This conductive wire has a small resistance value, and thus a large current can flow through the conductive wire, that is, the second conductive pattern. The cross-sectional area is the area of a plane through which a current passes.

In the above aspect, the integrated circuit device includes: an opposing surface that opposes the insulating layer; and a plurality of conduction portions that are disposed on the opposing surface and respectively electrically connected to the plurality of first conductive patterns.

In this aspect, the integrated circuit device is a BGA (Ball Grid Array), for example. A plurality of conduction portions, which are ball-shaped pieces of solder for example, that are electrically connected to the first conductive patterns are disposed on the opposing surface of the integrated circuit device. When this integrated circuit device is employed, the number of first conductive patterns that are electrically connected to the integrated circuit device is increased, and the thickness of the second conductive pattern is reduced. Thus, the busbar can operate more effectively.

In the above aspect, power is supplied via the second conductive pattern and the busbar.

In this aspect, the conductive wire formed by the second conductive pattern and the busbar is used to supply power.

In a circuit apparatus according to an aspect of the present disclosure, two or more of the second conductive patterns are provided, the busbar is bent, and the busbar includes two connection portions connected to two second conductive patterns, and a linking portion that links the two connection portions while being separated from the insulating layer.

In this aspect, a portion of the busbar is separated from the circuit board, and the area occupied by the busbar on the insulating layer is small. Thus, more conductive patterns can be disposed on the insulating layer.

Specific examples of a circuit apparatus according to an embodiment of the present disclosure are described below with reference to the drawings. Note that the present disclosure is not limited to these examples, but is indicated by the claims, and all changes that come within the meaning and range of equivalency of the claims are intended to be embraced therein.

### Embodiment 1

### Configuration of Circuit Apparatus

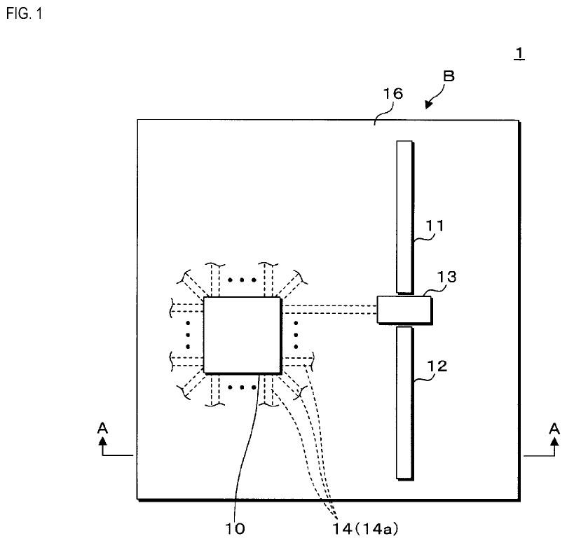

FIG. 1 is a plan view of a circuit apparatus 1 according to Embodiment 1. The circuit apparatus 1 includes a rectangular circuit board B. In the circuit apparatus 1, an integrated circuit device 10, busbars 11 and 12, and a switch circuit 13 are disposed on the circuit board B. Conductive patterns 14 are disposed inside the circuit board B. A plurality of first conductive patterns 14a of the conductive patterns 14 are electrically connected to the integrated circuit device 10. One first conductive pattern 14a is electrically connected to the switch circuit 13. The busbars 11 and 12 are rod-shaped conductors and are made of metal, for example. The busbars 11 and 12 are separately electrically connected to the switch circuit 13.

Note that, in FIG. 1, only three conductive patterns 14 are given reference numerals to keep the drawing from becoming complicated. All conductive patterns 14 shown with a broken line in FIG. 1 are first conductive patterns 14a.

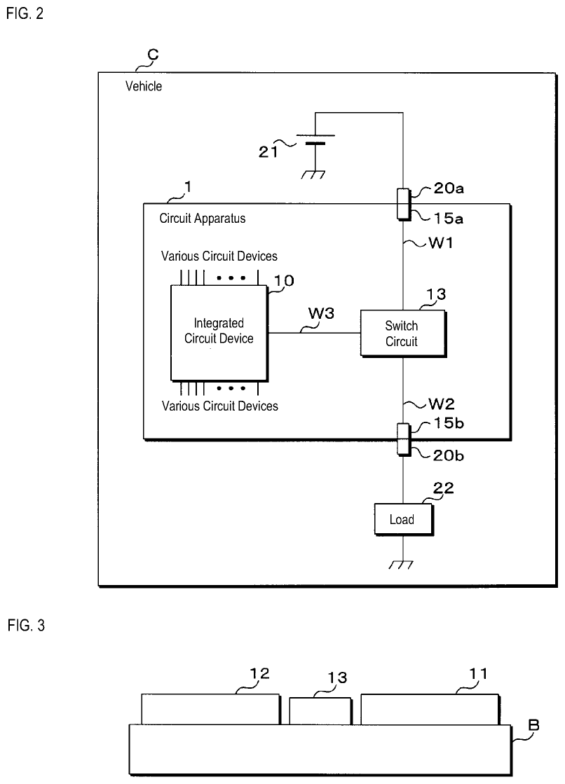

FIG. 2 is a block diagram showing main configurations of the circuit apparatus 1. The circuit apparatus 1 also includes apparatus connectors 15a and 15b. The switch circuit 13 and the apparatus connector 15a are connected to each other by a conductive wire W1. The switch circuit 13 and the apparatus connector 15b are connected to each other by a conductive wire W2. The integrated circuit device 10 and the switch circuit 13 are connected to each other by a conductive wire W3. The busbar 11 forms a part of the conductive wire W1. The busbar 12 forms a part of the conductive wire W2. The conductive wire W3 is formed by the first conductive pattern 14a that is electrically connected to the switch circuit 13. The integrated circuit device 10 is connected to various circuit devices via conductive wires. Each of these conductive wires is formed by a first conductive pattern 14a.

Note that the apparatus connectors 15a and 15b are not shown in FIG. 1.

The apparatus connectors 15a and 15b are respectively connected to external connectors 20a and 20b. The external connector 20a is connected to the positive electrode of a DC power supply 21. The negative electrode of the DC power supply 21 is grounded. The DC power supply 21 is a battery, for example. The external connector 20b is connected to one end of a load 22. The other end of the load 22 is grounded. The load 22 is an electrical device. The circuit apparatus 1, the DC power supply 21, and the load 22 are mounted in a vehicle C.

The integrated circuit device 10 functions as a micro-computer, for example. The first conductive patterns 14a are used to supply power to the integrated circuit device 10, output signals from the integrated circuit device 10, input signals to the integrated circuit device 10, and the like. The integrated circuit device 10 outputs an ON instruction and an OFF instruction to the switch 13.

The switch 13 turns on upon receiving an ON instruction from the integrated circuit device 10. When the switch 13 is on, the apparatus connectors 15a and 15b are connected to each other. A current flows from the positive electrode of the DC power supply 21 to the switch circuit 13, the load 22, and the negative electrode of the DC power supply 21 in this order. Thus, the DC power supply 21 supplies power to the load 22. The load 22 operates when supplied with power.

The switch circuit 13 turns off upon receiving an OFF instruction from the integrated circuit device 10. When the switch circuit 13 is off, connection between the apparatus connectors 15a and 15b is interrupted, and passage of a current from the DC power supply 21 to the load 22 is stopped. Consequently, the supply of power to the load 22 is stopped. When the supply of power to the load 22 is stopped, the load 22 stops operating.

When the switch circuit 13 is on, the DC power supply 21 supplies power to the load 22 via the conductive wires W1 and W2 whereby a large current flows through the conductive wires W1 and W2. Accordingly, when the switch circuit 13 is on, a large current flows via the busbars 11 and 12 shown in FIG. 1.

FIG. 3 is a side view of the circuit apparatus 1. As shown in FIGS. 1 and 3, the busbars 11 and 12 both have a straight rod shape and a rectangular cross-section. The switch circuit 13 is disposed between end surfaces of the busbars 11 and 12.

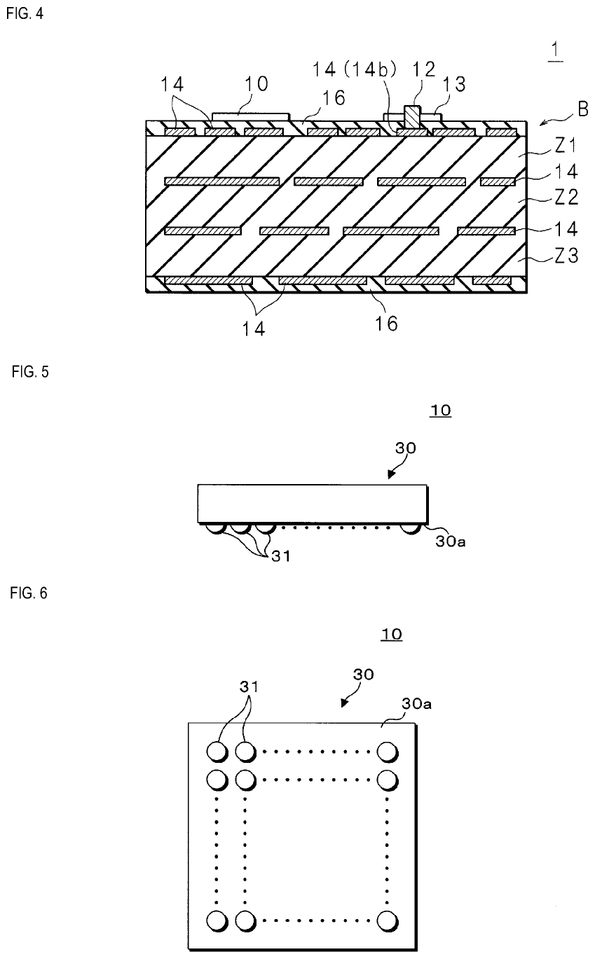

FIG. 4 is a cross-sectional view of the circuit apparatus 1 taken along the A-A line in FIG. 1. As shown in FIG. 4, in the circuit board B, three insulating layers Z1, Z2, and Z3 are arranged in this order from the upper side to the lower side of FIG. 4. The conductive patterns 14 are plate-shaped. A plurality of conductive patterns 14 are disposed between the insulating layers Z1 and Z2. The conductive patterns 14 are plate-shaped, and thus each has two wide surfaces with a large area. The two wide surfaces oppose each other. The two wide surfaces are continuous with narrow surfaces that have a small area. In FIG. 4, the upper and lower surfaces of each conductive pattern 14 are wide surfaces. The left and right surfaces of each conductive pattern 14 are narrow surfaces. The wide surfaces of the conductive patterns 14 disposed between the insulating layers Z1 and Z2 are level with each other. An insulating member is provided between two adjacent conductive patterns 14, and the insulating member links the insulating layers Z1 and Z2 to each other.

Similarly, a plurality of conductive patterns 14 are disposed between the insulating layers Z2 and Z3. The wide surfaces of these conductive patterns 14 are level with each other. An insulating member is disposed between two adjacent conductive patterns 14, and the insulating member links the insulating layers Z2 and Z3 to each other.

On one surface of the insulating layer Z1 on the upper side of FIG. 4 (hereinafter referred to as the “upper surface”), a plurality of conductive patterns 14 are disposed. The conductive patterns 14 disposed on the insulating layer Z1 are covered from the upper side of FIG. 4 by an insulative resist 16. The plurality of first conductive patterns 14a that are electrically connected to the integrated circuit device 10 are disposed on the upper surface of the insulating layer Z1.

The plurality of conductive patterns 14 provided in the circuit apparatus 1 include two second conductive patterns 14b that are respectively connected to the busbars 11 and 12. As shown in FIG. 4, one second conductive pattern 14b is disposed on the upper surface of the insulating layer Z1 and one wide surface of the second conductive pattern 14b opposes the upper surface of the insulating layer Z1. The busbar 12 is disposed on the other wide surface of the second conductive pattern 14b, and the second conductive pattern 14b is in contact with a side surface of the busbar 12. Accordingly, connection between the busbar 12 and the second conductive pattern 14b is realized.

Similarly, the other second conductive pattern 14b is also disposed on the upper surface of the insulating layer Z1, and one wide surface of the second conductive pattern 14b opposes the upper surface of the insulating layer Z1. The busbar 11 is disposed on the other wide surface of the second conductive pattern 14b, and the second conductive pattern 14b is in contact with a side surface of the busbar 11. Accordingly, connection between the busbar 11 and the second conductive pattern 14b is realized.

The conductive wire W1 shown in FIG. 2 is formed in a state where the busbar 11 and the second conductive pattern 14b overlap each other. The cross-sectional area of the conductive wire W1 is large, and the resistance value of the conductive wire W1 is small. A large current flows via the second conductive pattern 14b and the busbar 11. Similarly, the conductive wire W2 is formed in a state where the busbar 12 and the second conductive pattern 14b overlap each other. The cross-sectional area of the conductive wire W2 is large, and the resistance value of the conductive wire W2 is small. A large current flows via the second conductive pattern 14b and the busbar 12.

Here, the cross-sectional area is the area of a plane in a direction that is perpendicular to the direction in which a current flows. In other words, the cross-sectional area is the area of a plane through which a current passes.

On one surface of the insulating layer Z3 on the lower side of FIG. 4 (hereinafter referred to as the “lower surface”), a plurality of conductive patterns 14 are also disposed. These conductive patterns 14 are also covered from the lower side of FIG. 4 by a resist 16.

As described above, in the circuit apparatus 1, a first layer is formed by the plurality of conductive patterns 14 disposed on the upper surface of the insulating layer Z1. A second layer is formed by the plurality of conductive patterns 14 disposed between the insulating layers Z1 and Z2. A third layer is formed by the plurality of conductive patterns 14 disposed between the insulating layers Z2 and Z3. A fourth layer is formed by the plurality of conductive patterns 14 disposed on the lower surface of the insulating layer Z3.

One or more holes (not shown) are formed in each of the insulating layers Z1, Z2, and Z3. These holes are called “vias”. The inner surface of each hole is plated with a conductive material. Two conductive patterns 14 respectively disposed in two layers are electrically connected to each other by the plating. FIG. 4 also shows a conductive pattern that is different from the first conductive patterns 14a and the second conductive patterns 14b.

Note that, in FIG. 4, only five conductive patterns 14 are given reference symbols to keep the diagram from becoming complicated.

Also, the number of insulating layers included in the circuit apparatus 1 is not limited to three, and may be one, two, four or more. A plurality of conductive patterns 14 are disposed between each pair of insulating layers as described above. Below, the insulating layer Z1 is described as the insulting layer located on the uppermost side of FIG. 4.

### Configuration of Integrated Circuit Device 10

FIG. 5 is a side view of the integrated circuit device 10. FIG. 6 is a bottom view of the integrated circuit device 10. The upper surface of the integrated circuit device 10 is shown in FIG. 1. The integrated circuit device 10 is a so-called BGA. The integrated circuit device 10 includes a rectangular parallelopiped device main body 30. As shown in FIG. 6, solder balls 31 are arranged in the form of a lattice on a bottom surface 30a of the device main body 30.

Note that it is sufficient that a plurality of solder balls 31 are disposed on the bottom surface 30a of the device main body 30. Thus, the solder balls 31 are not limited to being arranged in the form of a lattice.

The solder balls 31 are ball-shaped pieces of conductive solder. The bottom surface 30a of the integrated circuit device 10 opposes the upper surface of the insulating layer Z1 shown in FIG. 4. Each solder ball 31 is melted and connected to one conductive pattern 14. The integrated circuit device 10 is electrically connected to each conductive pattern 14 disposed on the upper surface of the insulating layer Z1 via the corresponding solder ball 31.

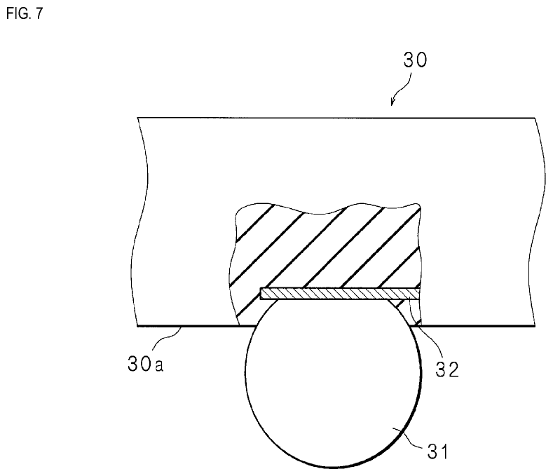

FIG. 7 is a diagram for describing the location of an electrode 32 of the integrated circuit device 10. FIG. 7 shows an internal portion of the device main body 30. As shown in FIG. 7, the electrode 32 is disposed inside the device main body 30 of the integrated circuit device 10. A solder ball 31 is connected to the electrode 32. The solder ball 31 and the electrode 32 are electrically connected to each other. The electrode 32 is covered by an insulating body inside the device main body 30.

The number of electrodes 32 included in the integrated circuit device 10 usually matches the number of solder balls 31 disposed on the bottom surface 30a of the device main body 30. As described above, each electrode 32 is located inside the device main body 30 and electrically connected to a solder ball 31.

### Connection of First Conductive Pattern 14a to Integrated Circuit Device 10

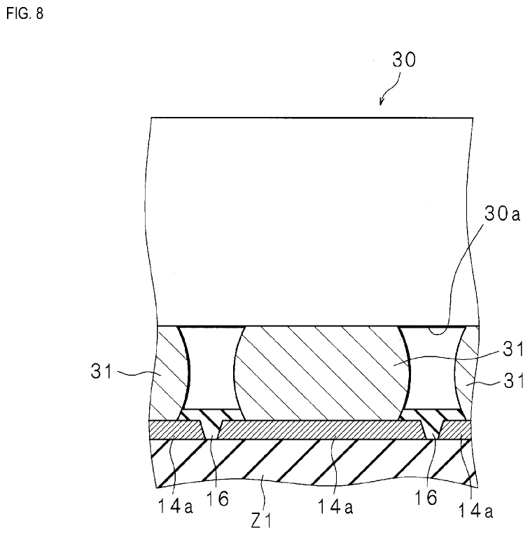

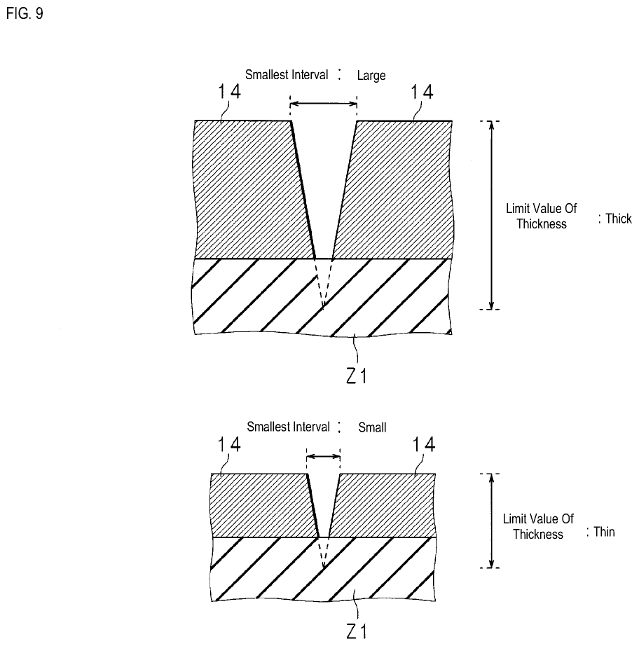

FIG. 8 is a diagram for describing connection of the first conductive patterns 14a to the integrated circuit device 10. FIG. 8 shows cross-sections of portions other than the device main body 30 of the integrated circuit device 10. As described above, a plurality of first conductive patterns 14a are disposed on the upper surface of the insulating layer Z1. The integrated circuit device 10 is disposed above the first conductive patterns 14a. The bottom surface 30a of the device main body 30 of the integrated circuit device 10 opposes the upper surface of the insulating layer Z1 and functions as an opposing surface.

One wide surface of each first conductive pattern 14a is in contact with the upper surface of the insulating layer Z1. The other wide surface of each first conductive pattern 14a is in contact with a solder ball 31 of the integrated circuit device 10. Thus, the solder balls 31 are respectively electrically connected to the first conductive patterns 14a. Each solder ball 31 functions as a conduction portion.

The first conductive patterns 14a are connected to the solder balls 31, and thus the electrodes 32 of the device main body 30 of the integrated circuit device 10 are connected to the first conductive patterns 14a by the solder balls 31. A portion of each first conductive pattern 14a is covered from the upper side of FIG. 8 by the resist 16.

### Thickness of Conductive Pattern 14

As shown in FIG. 6, there are many solder balls 31 arranged on the bottom surface 30a of the device main body 30 of the integrated circuit device 10. As described above, each first conductive pattern 14a is connected to one solder ball 31. Thus, the first conductive patterns 14a are in close proximity to each other. Accordingly, each first conductive pattern 14a has a small width of less than 0.15 mm, for example. When the first conductive patterns 14a are in close proximity to each other, the thickness of the conductive patterns 14 disposed on the upper surface of the insulating layer Z1 is determined by the smallest interval between the two first conductive patterns 14 that are closest to each other.

The smallest interval is smaller than or equal to the distance between the two first conductive patterns 14a that are closest to each other. Accordingly, the smallest interval in the circuit apparatus 1 including the integrated circuit device 10 is small. The smaller the smallest interval, the smaller the thickness of the conductive patterns 14 disposed on the upper surface of the insulating layer Z1. The relation between the smallest interval and the thickness of the conductive patterns 14 is described below.

FIG. 9 is a diagram for describing a relation between the smallest interval and the thickness of the conductive patterns 14. FIG. 9 shows a cross-section of the insulating layer Z1 and a cross-section of the two conductive patterns 14 closest to each other. When forming a plurality of conductive patterns 14, a conductive plate whose wide surfaces have a large area is disposed on the insulating layer Z1 and subjected to etching. This forms the narrow surfaces of the conductive patterns 14. As shown in FIG. 9, the narrow surfaces of the conductive patterns 14 are not perpendicular, but inclined relative to the upper surface of the insulating layer Z1. The distance between two adjacent conductive patterns 14 decreases in a direction toward the insulating layer Z1.

Two adjacent conductive patterns 14 need to be arranged so as not to be in contact with each other. The limit value of the thickness of a conductive pattern 14 is the thickness of a conductive pattern 14 when the cross-sectional surfaces of two conductive patterns 14 are in contact with each other. Thus, when the smallest interval is large, as shown on the upper side of FIG. 9, thin conductive patterns 14 can be disposed on the upper surface of the insulating layer Z1. However, in the case where the smallest interval is small, as shown on the lower side of FIG. 9, thick conductive patterns 14 cannot be disposed on the upper surface of the insulating layer Z1.

When a conductive pattern 14 is thin, the cross-sectional area of the conductive pattern 14 is small, and thus the resistance value of the conductive pattern 14 is large. In the case where the resistance value of the conductive pattern 14 is large, there is a possibility that the temperature of the conductive pattern 14 will rise to an abnormal temperature when a large current flows through the conductive pattern 14. Thus, when the resistance value of the conductive pattern 14 is large, a large current cannot be passed through the conductive pattern 14.

Normally, currents that flow via the first conductive patterns 14a electrically connected to the integrated circuit device 10 are small. Thus, even if the resistance value of the first conductive patterns 14a is large, the integrated circuit device 10 can operate properly. However, in the circuit apparatus 1 including the integrated circuit device 10, the smallest interval is small, and thus the second conductive patterns 14b disposed on the insulating layer Z1 are also thin. Consequently, the cross-sectional area of each second conductive pattern 14b is small, and the resistance value of the second conductive patterns 14b is large. Accordingly, a current that can flow only using the second conductive patterns 14b is small. Thus, in the circuit apparatus 1, using the busbars 11 and 12 makes it possible to allow a large current to flow via the second conductive patterns 14b.

### Effect of Busbar 11

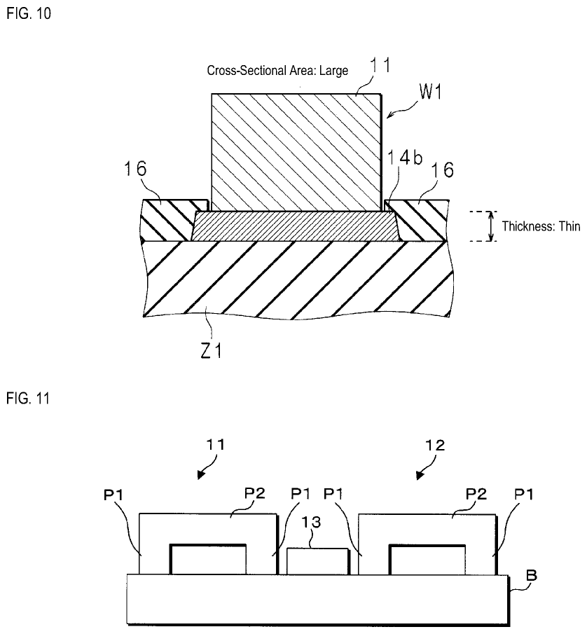

FIG. 10 is a diagram for describing effects of the busbar 11. FIG. 10 shows cross-sections of the busbar 11, the second conductive pattern 14b, the resist 16, and the insulating layer Z1. As shown in FIG. 10, a side surface of the busbar 11 is in contact with the second conductive pattern 14b, and the busbar 11 is connected to the second conductive pattern 14b. As described above, the busbar 11 and the second conductive pattern 14b function as the conductive wire W1 in an overlapping state. As shown in FIG. 10, the second conductive pattern 14b is thin. However, the conductive wire W1 has a large cross-sectional area. Thus, a large current can flow through the conductive wire W1, that is, the busbar 11 and the second conductive pattern 14b. As described above, when the switch circuit 13 is on, power is supplied from the DC power supply 21 to the load 22 via the conductive wire W1.

As described above, by using the busbar 11, a large current can flow through the second conductive patterns 14b disposed on the same insulating layer Z1 as the first conductive patterns 14a electrically connected to the integrated circuit device 10.

Assume that an X (mm) width of the second conductive pattern 14b is required in order for a current X (A) to be able to flow only using the second conductive patterns 14b. Here, X is a positive real number. By overlaying the busbar 11 and the second conductive pattern 14b on each other, the limit on the width of the second conductive pattern 14b required for an X [A] current to flow is eased to a width of X/2 [mm] or less, for example.

The busbar 12 is disposed on the second conductive pattern 14b similarly to the busbar 11. The busbar 12 and the second conductive pattern 14b function as the conductive wire W2 in an overlapping state. The cross-sectional area of the conductive wire W2 is large and the resistance value of the conductive wire W2 is small. Thus, a large current can flow through the conductive wire W2, that is, the busbar 12 and the second conductive pattern 14b. As described above, when the switch circuit 13 is on, power is supplied from the DC power supply 21 to the load 22 via the conductive wire W2. The current that flows through the conductive wires W1 and W2 is a current that flows from the DC power supply 21 to the load 22 via the switch circuit 13.

As described above, the integrated circuit device 10 is a BGA. Thus, the solder balls 31 that are electrically connected to the first conductive patterns 14a are disposed on the opposing surface of the device main body 30 of the integrated circuit device 10. When the integrated circuit device 10 is a BGA, the number of first conductive patterns 14a electrically connected to the integrated circuit device 10 is increased, and the thickness of the second conductive patterns 14b is reduced. Therefore, the busbars 11 and 12 operate more effectively.

### Embodiment 2

In Embodiment 1, the busbars 11 and 12 each have a straight rod shape. However, the shape of the busbars 11 and 12 is not limited to a straight rod shape.

Points regarding Embodiment 2 that differ from those of Embodiment 1 are described below. Configurations excluding those described below are the same as those of Embodiment 1. Thus, constituent portions that are the same as those in Embodiment 1 are given the same reference numerals as those in Embodiment 1 and description thereof is omitted.

### Shape of Busbars 11 and 12

FIG. 11 is a side view of the circuit apparatus 1 of Embodiment 2. The plan view of the circuit apparatus 1 of Embodiment 2 is similar to that shown in FIG. 1. The busbars 11 and 12 are both bent and each include two connection portions P1 and a linking portion P2 that links the two connection portions. The connection portions P1 and the linking portion P2 are rod shaped. One end portion of each connection portion P1 is in contact with a wide surface of a second conductive pattern 14b of the circuit board B. Thus, the connection portions P1 are respectively connected to the second conductive patterns 14b. The linking portion P2 is linked to the other end portions of the two corresponding connection portions P1. The linking portions P2 are separated from the circuit board B, that is, the upper surface of the insulating layer Z1.

### Connection Between Second Conductive Pattern 14b and Connection Portion P1

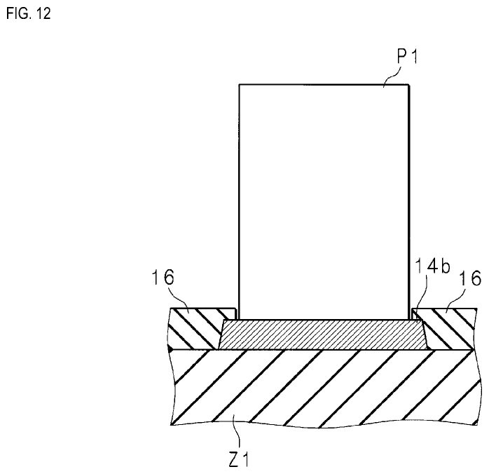

FIG. 12 is a diagram for describing connection between the second conductive pattern 14b and the connection portion P1. In the circuit apparatus 1 of Embodiment 2, four second conductive patterns 14b are disposed on the upper surface of the insulating layer Z1. As shown in FIG. 10, one end surface of the connection portion P1 is in contact with a wide surface of the second conductive pattern 14b. Thus, the connection portion P1 is connected to the second conductive pattern 14b.

The two connection portions P1 of the busbar 11 respectively overlap two second conductive patterns 14b. In a state where the busbar 11 is overlaid on two second conductive patterns 14b, the busbar 11 and the two second conductive patterns 14b function as the conductive wire W1. The conductive wire W1 includes the portions where the second conductive patterns 14b and the connection portions P1 overlap, and the portion formed by the linking portion P2.

The busbar 11 has a large cross-sectional area. Thus, the resistance value of the busbar 11 is small, and a large current can flow through the busbar 11. The portions where the second conductive patterns 14b are present are overlapped by the connection portions P1 of the busbar 11, and thus a large current can flow through the second conductive patterns 14b. As described above, the resistance value of the busbar 11 is small, and thus a large current can flow through the linking portion P2. As a result, a large current can flow through the conductive wire W1.

Similarly, the two connection portions P1 of the busbar 12 respectively overlap two second conductive patterns 14b. In a state where the busbar 12 is overlaid on two second conductive patterns 14b, the busbar 12 and the two second conductive patterns 14b function as the conductive wire W2. The conductive wire W2 includes the portions where the second conductive patterns 14b and the connection portions P1 overlap, and the portion formed by the linking portion P2.

The busbar 12 has a large cross-sectional area. Thus, the resistance value of the busbar 12 is small, and a large current can flow through the busbar 12. The portions where the second conductive patterns 14b are present are overlapped by the connection portions P1 of the busbar 12. Also, the resistance value of the busbar 12 is small, and thus a large current can flow through the linking portion P2. As a result, a large current can flow through the conductive wire W2.

### Effects of Circuit Apparatus 1

The linking portions P2 of the busbars 11 and 12 are separated from the circuit board B, that is, the upper surface of the insulating layer Z1, and the area occupied by the busbars 11 and 12 on the upper surface of the insulating layer Z1 is small. Thus, more conductive patterns 14 can be disposed on the insulating layer Z1.

The circuit apparatus 1 of Embodiment 2 exhibits the same effects as those exhibited by the circuit apparatus 1 of Embodiment 1.

### Notes

In Embodiment 2, both of the busbars 11 and 12 do not necessarily need to be bent. Accordingly, the shape of one of the busbars 11 and 12 may be a straight rod shape. That is, in the circuit apparatus 1, a busbar that has a straight rod shape and a busbar that has two connection portions P1 and a linking portion P2 may be provided.

### Variations

In Embodiments 1 and 2, a current that flows through the conductive wires W1 and W2 is not limited to a current used in power supply, and may be a current that cannot flow through the conductive patterns 14 alone. The number of busbars included in the circuit apparatus 1 is not limited to two, and may be one or three or more.

In Embodiments 1 and 2, the integrated circuit device 10 is not limited to a BGA. The integrated circuit device 10 does not necessarily need to include a plurality of solder balls 31. In this case, for example, the electrodes 32 protrude from the bottom surface 30a of the device main body 30. Also, the integrated circuit device 10 may employ a configuration where the electrodes 32 are exposed from four side surfaces that are continuous with the bottom surface 30a instead of from the bottom surface 30a. The number of integrated circuit devices of the circuit apparatus 1 is not limited to one, and may be two or more.

The disclosed Embodiments 1 and 2 are to be considered illustrative in all respects and not restrictive. The scope of the present disclosure is defined by the claims and not by the above description, and all changes that come within the meaning and range of equivalency of the claims are intended to be embraced therein.

1. A circuit apparatus to be mounted in a vehicle, comprising:
an insulating layer;
a plurality of first conductive patterns and a second conductive pattern disposed on the insulating layer;
an integrated circuit device disposed on and electrically connected to the plurality of first conductive patterns; and
a busbar that is connected to the second conductive pattern.

2. The circuit apparatus according to claim 1,
wherein the integrated circuit device includes:
an opposing surface that opposes the insulating layer; and
a plurality of conduction portions that are disposed on the opposing surface and respectively electrically connected to the plurality of first conductive patterns.

3. The circuit apparatus according to claim 1, wherein power is supplied via the second conductive pattern and the busbar.

4. The circuit apparatus according to claim 1,
wherein two or more of the second conductive patterns are provided,
the busbar is bent, and
the busbar includes two connection portions connected to two second conductive patterns, and a linking portion that links the two connection portions while being separated from the insulating layer.

5. The circuit apparatus according to claim 2, wherein power is supplied via the second conductive pattern and the busbar.

6. The circuit apparatus according to claim 2,
wherein two or more of the second conductive patterns are provided,
the busbar is bent, and
the busbar includes two connection portions connected to two second conductive patterns, and a linking portion that links the two connection portions while being separated from the insulating layer.

7. The circuit apparatus according to claim 3,
wherein two or more of the second conductive patterns are provided,
the busbar is bent, and
the busbar includes two connection portions connected to two second conductive patterns, and a linking portion that links the two connection portions while being separated from the insulating layer.
